(19) United States
(12) Patent Application Publication
(10) Pub. No.: US 2026/0114335 A1
(43) Pub. Date: Apr. 23, 2026

(54) INTERPOSER WITH EMBEDDED WIRE BOND REDISTRIBUTION STRUCTURES

(71) Applicant: Micron Technology, Inc., Boise, ID (US)

(72) Inventors: Kelvin Aik Boo TAN, Singapore (SG); Hong Wan NG, Singapore (SG); See Hiong LEOW, Singapore (SG); Seng Kim YE, Singapore (SG); Ling PAN, Singapore (SG); Chin Hui CHONG, Singapore (SG)

(21) Appl. No.: 19/308,870

(22) Filed: Aug. 25, 2025

Related U.S. Application Data
(60) Provisional application No. 63/708,469, filed on Oct. 17, 2024.

(51) Int. Cl. H01L 23/498; H01L 23/00; H01L 23/31; H01L 25/00; H01L 25/16

(52) U.S. Cl. CPC H10W 90/701; H10W 70/65; H10W 74/117; H10W 90/00; H10W 90/754

(57) ABSTRACT

Implementations described herein relate to various semiconductor device assemblies. In some implementations, an apparatus includes a first integrated circuit, a second integrated circuit, and an interposer that is part of an electrical circuit that electrically couples the first integrated circuit and the second integrated circuit. The interposer includes a casing and at least one malleable, conductive wire that is embedded in the casing and that is contoured to reroute a signal through the casing.

### CROSS-REFERENCE TO RELATED APPLICATION

This patent application claims priority to U.S. Provisional Patent Application No. 63/708,469, filed on Oct. 17, 2024, entitled “INTERPOSER WITH EMBEDDED WIRE BOND REDISTRIBUTION STRUCTURES,” and assigned to the assignee hereof. The disclosure of the prior application is considered part of and is incorporated by reference into this patent application.

### TECHNICAL FIELD

The present disclosure generally relates to semiconductor devices and methods of forming semiconductor devices. For example, the present disclosure relates to an interposer with embedded wire bond redistribution structures.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example device that may be manufactured using techniques described herein.

FIG. 3 shows an example implementation of an interposer described herein.

FIG. 4 shows an example implementation of an interposer described herein.

FIG. 5 is a flowchart of an example method of forming an interposer described herein.

FIG. 6 is a flowchart of an example method of forming an integrated assembly or device having an interposer described herein.

FIGS. 7A-7I are diagrammatic views showing formation of an interposer at stages of an example process of forming the interposer.

### DETAILED DESCRIPTION

In the realm of semiconductor packaging, achieving a thinner profile for semiconductor packages has become desirable as the electronics industry shifts towards more compact and efficient devices. With the tendency to reduce the form factor of semiconductor packages, there is growing pressure to conserve space within the semiconductor package while maintaining or enhancing performance.

In some cases, and as part of reducing space and/or enhancing performance, a semiconductor package may rely on silicon or ceramic substrates that include redistribution layers (RDLs) and/or through silicon vias (TSVs). However, use of the RDLs and TSVs may increase cost of the semiconductor package, add complexities to manufacturing, consume additional resources, and/or add to a cycle time of delivery.

In other cases, wire bonding techniques, which have been a mainstay in semiconductor packaging, face challenges when it comes to miniaturization. For example, a wire bonding tool may not have the capability to create certain angles or arc patterns required for proper connectivity within the reduced space, and attempts to do so can lead to issues like wire sweep or shorting.

Some implementations described herein include an interposer with embedded wire bond redistribution structures and methods of manufacturing. The interposer may be formed using available wire bonding techniques, and enable robust electrical interconnectivity for rerouting and/or fan-out of electrical signals transmitted through an electronic device such as a semiconductor package, a memory module, a solid state drive, a server board, and/or nearly any other apparatus with integrated circuitry. The interposer may accommodate electrical signal rerouting challenges by incorporating a contoured formation of wire bonds within the interposer that may adhere to non-linear paths, aptly addressing constraints related to tight spacing and the need for electrical interconnectivity across a range of angular needs.

In some implementations, the manufacture of the interposer is facilitated by forming conductive input and output structures upon a temporary carrier, then instituting a pattern of conductive wires to establish intricate connections between those structures, followed by the encapsulation of the assembly in a casing before the eventual removal of the carrier.

The interposer may be positioned atop a substrate, an integrated circuit die, or even stacked with other integrated circuit dies, demonstrating adaptability and flexibility with any number of electronic devices. Furthermore, the interposer may obviate a need for spacers, manage a constricted space, and/or mitigate issues prevalent in traditional wire bonding (e.g., wire sweep or shorting, particularly in the context of certain angular connections).

In this way, an electronic device using the interposer may satisfy a form factor threshold and reroute electrical signaling without a compromise in performance. Furthermore, techniques to manufacture the interposer may be simplified relative to techniques that rely on RDLs to consume fewer resources (e.g., raw materials, manufacturing tools, labor and/or computing resources), thereby enhancing both the technical efficiency and the cost-efficiency of manufacturing the electronic device.

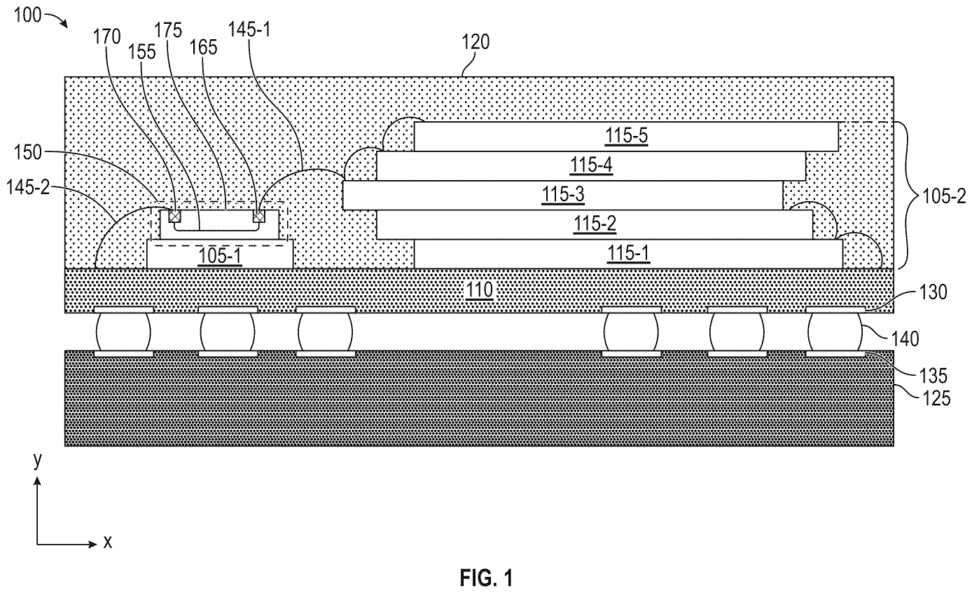

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a shingle stack (e.g., with die edges that are not aligned, which provides space for wire bonding near the edges of the dies 115), in some implementations, the dies 115 may be stacked in a different arrangement, such as a straight stack (e.g., with aligned die edges).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

Within the apparatus 100, one or more wire bonds 145 (e.g., malleable, conductive wires formed from gold (Au), aluminum (Al), copper (Cu), silver (Ag), or another suitable malleable and conductive material) may electrically couple the integrated circuit 105-1 with the integrated circuit 105-2 through an interposer 150. For example, and as shown in FIG. 1, the wire bond 145-1 electrically couples the integrated circuit 105-2 with the interposer 150, and the wire bond 145-2 electrically couples the interposer 150 with the substrate 110. In some implementations, the substrate 110 electrically couples with the integrated circuit 105-1 using a trace in the substrate 110, a solder ball, another wire bond, or another suitable electrical connection. In other words, the wire bond 145-1, the wire bond 145-2, the interposer 150, and the substrate 110 may be part of an electrical circuit that electrically couples the integrated circuit 105-1 with the integrated circuit 105-2.

In some implementations, and as shown in FIG. 1, the interposer 150 is a “stepping stone” that is over and/or on an integrated circuit (e.g., the integrated circuit 105-1). Alternatively, and in some implementations, the interposer 150 may be over and/or on the substrate 110.

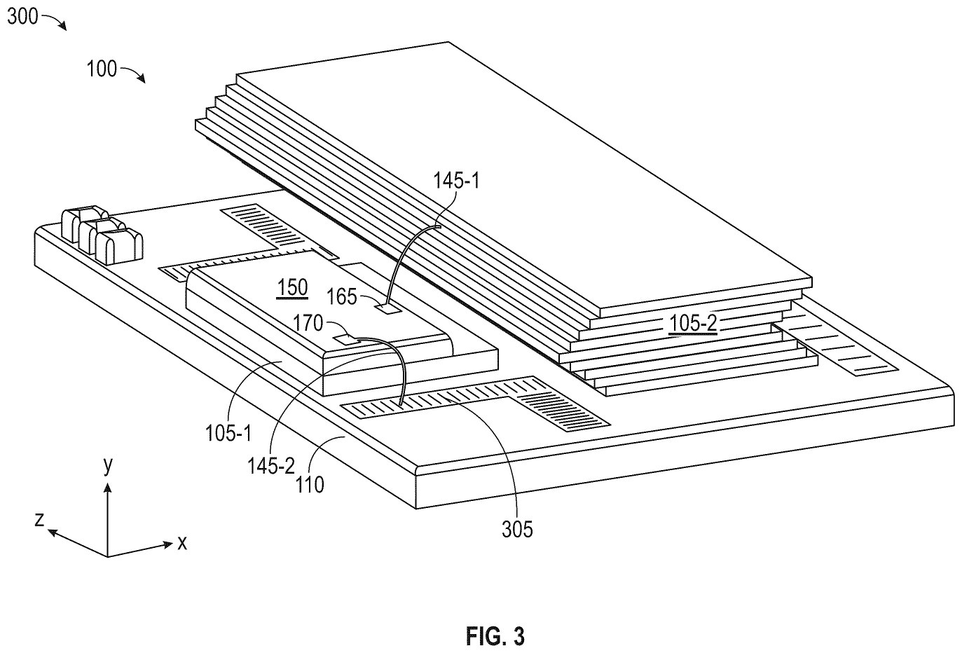

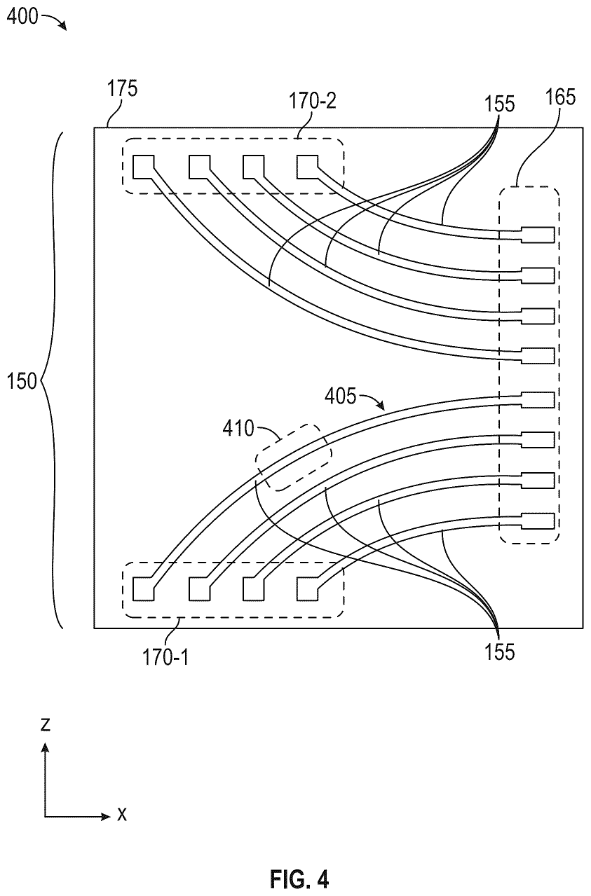

In some implementations, the interposer 150 is a passive interposer and is void of active integrated circuitry (e.g., void of transistors, diodes, or other devices that can amplify, switch, or process electronic signals). Additionally, or alternatively and as described in greater detail in connection with FIG. 4, some implementations of the interposer 150 may include passive components such as embedded capacitors, embedded resistors, and/or the like.

As shown in FIG. 1, the interposer 150 includes a pattern of wire bonds 155 (e.g., a plurality of wire bonds) that are electrically coupled with input structures 165 and output structures 170. The pattern of wire bonds 155 may be used to redistribute and/or reroute electrical signals from the input structures 165 to the output structures 170. In some implementations the input structures 165 and/or the output structures 170 are electrical contacts (e.g., conductive pads, conductive posts, or conductive pillars) that are formed from a conductive material such as copper (Cu), tin (Sn), gold (Au), silver (Ag), nickel (Ni), or another suitable conductive material. As described in greater detail in connection with FIG. 3, FIG. 4, and elsewhere herein, the pattern of wire bonds 155 may fan out and include non-linear routing to redistribute electrical signals from the input structures 165 to the output structures 170.

As further shown in FIG. 1, a casing 175 surrounds the pattern of wire bonds 155. The casing 175 may include a non-conductive material such as an epoxy mold compound, a thermoset plastic material, a liquid crystal polymer, or another suitable non-conductive material. As shown in FIG. 1, the input structures 165 and/or the output structures 170 may be exposed along a surface of the casing 175. Additionally, or alternatively, the input structures 165 and/or the output structures 170 may penetrate into the casing 175.

As indicated above, FIG. 1 is provided as an example. Other examples may differ from what is described with regard to FIG. 1.

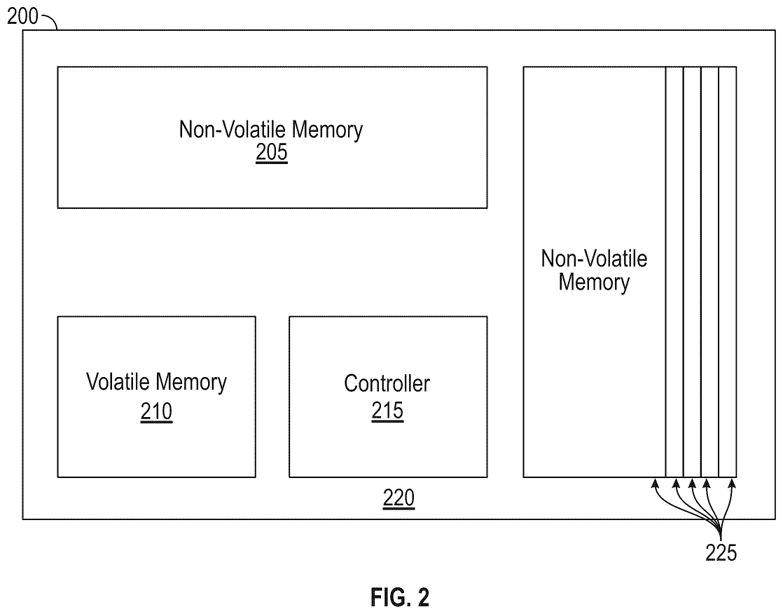

FIG. 2 is a diagram of an example device 200 that may be manufactured using techniques described herein. The device 200 is an example of the apparatus 100 described above in connection with FIG. 1 (e.g., including the interposer 150). The device 200 may be a semiconductor package, a multi-die semiconductor package, a memory module, a solid state drive, a server board, a graphics card, a network interface card, a backplane interface board, or a power supply board, among other examples.

In some implementations, the device 200 may be any electronic device configured to store data in memory. In some implementations, the device 200 may be an electronic device configured to store data persistently in non-volatile memory 205. For example, the device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the device 200 may include non-volatile memory 205, volatile memory 210, and a controller 215. The components of the device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the device 200 is powered off. For example, the non-volatile memory 205 may include NAND memory or NOR memory. The volatile memory 210 may require power to maintain stored data and may lose stored data after the device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the device 200). For example, the controller 215 may include a memory controller, a system controller, an ASIC, an FPGA, a processor, a microcontroller, and/or one or more processing components. In some implementations, the device 200 may be included in a system that includes the host device. The host device may include one or more processors configured to execute instructions and store data in the non-volatile memory 205.

The controller 215 may be configured to control operations of the device 200, such as by executing one or more instructions (sometimes called commands). For example, the device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

FIG. 3 shows an example implementation 300 of an interposer (e.g. the interposer 150) described herein. In FIG. 3, implementation 300 shows an isometric view that corresponds to an implementation of the apparatus 100, including the wire bond 145-1, the interposer 150, and the wire bond 145-2. Additional wire bonds that may be included in implementation 300 are omitted from FIG. 3 for clarity.

As shown in FIG. 3, the integrated circuit 105-2, which may include NAND integrated circuitry, is over and/or on the substrate 110. Furthermore, the integrated circuit 105-1, which may include application specific integrated circuitry, is over and/or on the substrate 110. As part of implementation 300, the interposer 150 serves to redistribute and/or reroute an electrical signal between the integrated circuit 105-1 and the integrated circuit 105-2 through the substrate 110. To redistribute and/or reroute the electrical signal, the wire bond 145-1 electrically couples the integrated circuit 105-2 with the input structure 165, and the wire bond 145-2 electrically couples the output structure 170 to a pad structure included in a pattern of pad structures 305 on the substrate. As shown in FIG. 3, the pattern of pad structures 305 may be an L-shaped pattern. The pattern of pad structures 305 may electrically couple to the integrated circuit 105-1 through electrical traces included in the substrate 110.

As shown in FIG. 3, the wire bond 145-1 extends directionally along the x-axis, and the wire bond 145-2 extends directionally along the z-axis. In other words, the wire bond 145-1 and the wire bond 145-2 are approximately orthogonal to each other. As described in greater detail in connection with FIG. 4, a pattern of wire bonds (e.g., the pattern of wire bonds 155) may be encapsulated within the interposer 150 and assist with redistribution and/or rerouting of electrical signals.

In implementation 300, the integrated circuit 105-1 may include application specific integrated circuitry (ASIC), and the integrated circuit 105-2 may include NAND integrated circuitry. Furthermore, using the interposer 150 may enable the apparatus to satisfy a semiconductor package height threshold (e.g., a maximum height threshold of approximately 0.8 millimeters).

As indicated above, FIG. 3 is provided as an example. Other examples may differ from what is described with regard to FIG. 3.

FIG. 4 shows an example implementation 400 of an interposer described herein (e.g., the interposer 150). In FIG. 4, implementation 400 shows a plan view of the interposer 150 including the pattern of wire bonds 155 embedded in the casing 175, the input structures 165 at a surface of the casing 175, and the output structures 170 (e.g., the output structures 170-1 and 170-2) at a surface of the casing 175.

As shown in FIG. 4, the input structures 165 are along a first edge of the interposer 150. Furthermore, the output structures 170-1 (e.g., a first subset of the output structures 170) are along a second edge of the interposer 150 that is approximately orthogonal to the first edge, and the output structures 170-2 (a second subset of the output structures 170) are along a third edge of the interposer 150 that is approximately orthogonal to the first edge and that is opposite the second edge.

As shown in FIG. 4, opposite ends (e.g., first ends and second ends) of the pattern of wire bonds 155 are connected to the input structures 165 and the output structures 170. Furthermore, at least one wire bond included in the pattern of wire bonds 155 follows a non-linear path 405 (e.g., a contoured path that includes a curvature or an arc) as part of “fanning out” the pattern of wire bonds 155.

The interposer 150 may be void of active integrated circuit components (e.g., components having integrated circuitry that is capable of amplifying or switching an electrical signal). However, in some implementations and as shown in FIG. 4, the interposer 150 may include at least one passive integrated circuit component 410. The passive integrated circuit component 410 (e.g., a component having integrated circuitry that is not capable of amplifying or switching an electrical signal) may include a resistor component, a capacitor component, or an inductor component, among other examples.

As indicated above, FIG. 4 is provided as an example. Other examples may differ from what is described with regard to FIG. 4.

As described in connection with FIGS. 1-4, and in some implementations, a semiconductor device assembly (e.g., the apparatus 100) includes an integrated circuit die (e.g., the die 115), a substrate (e.g., the substrate 110), and an interposer (e.g., the interposer 150) that electrically couples the integrated circuit die and the substrate. The interposer includes a pattern of wire bonds (e.g., the pattern of wire bonds 155) used to redistribute electrical signals from inputs (e.g., the input structures 165) of the interposer to outputs (e.g., the output structures 170) of the interposer and an epoxy mold compound (e.g., the casing) that surrounds the pattern of wire bonds.

Additionally, or alternatively, and in some implementations, an apparatus (e.g., the apparatus 100 or the device 200) includes a first integrated circuit (e.g., the integrated circuit 105-1), a second integrated circuit (e.g., the integrated circuit 105-2), and an interposer (e.g., the interposer 150) that is part of an electrical circuit that electrically couples the first integrated circuit and the second integrated circuit. The interposer includes a casing (e.g., the casing 175) and at least one malleable, conductive wire (e.g., a wire bond of the pattern of wire bonds 155) that is embedded in the casing and that is contoured to reroute a signal through the casing.

Additionally, or alternatively, and in some implementations, an interposer (e.g., the interposer 150) includes a plurality of wire bonds (e.g., the pattern of wire bonds 155) and a casing (e.g., the casing 175) that surrounds the plurality of wire bonds. The apparatus includes first wire bond pads (e.g., the input structures 165) exposed at a surface of the casing that connect to first ends of the plurality of wire bonds, and second wire bond pads (e.g., the output structures 170) exposed at the surface of the casing that connect to second ends of the plurality of wire bonds.

In these ways, an electronic device using the interposer 150 may satisfy a form factor threshold (e.g., a package height threshold of 0.8 millimeters) and reroute electrical signaling without a compromise in performance. Furthermore, techniques to manufacture the interposer 150 may be simplified relative to techniques that rely on RDLs and/or TSVs to consume fewer resources (e.g., raw materials, manufacturing tools, labor and/or computing resources), thereby enhancing both the technical efficiency and the cost-efficiency of manufacturing the electronic device, without reducing technical aspects of electrical interconnectivity.

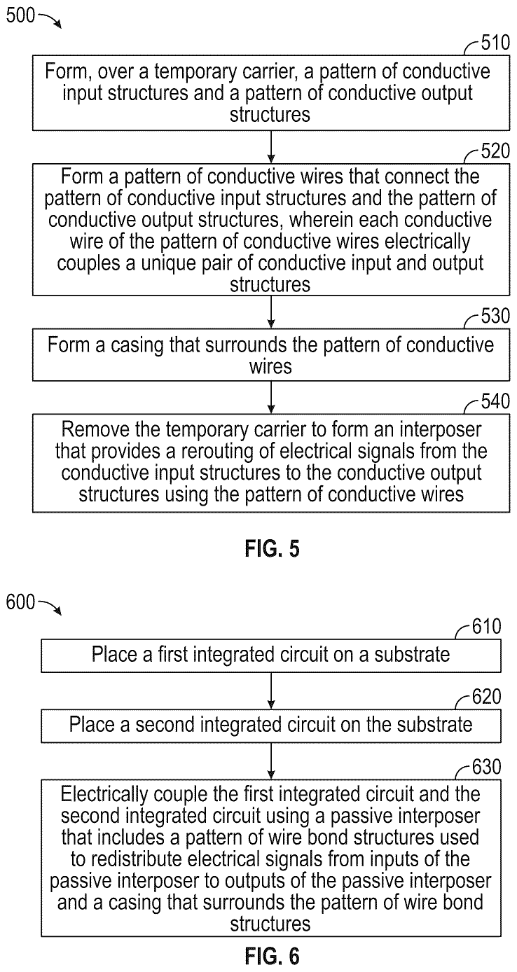

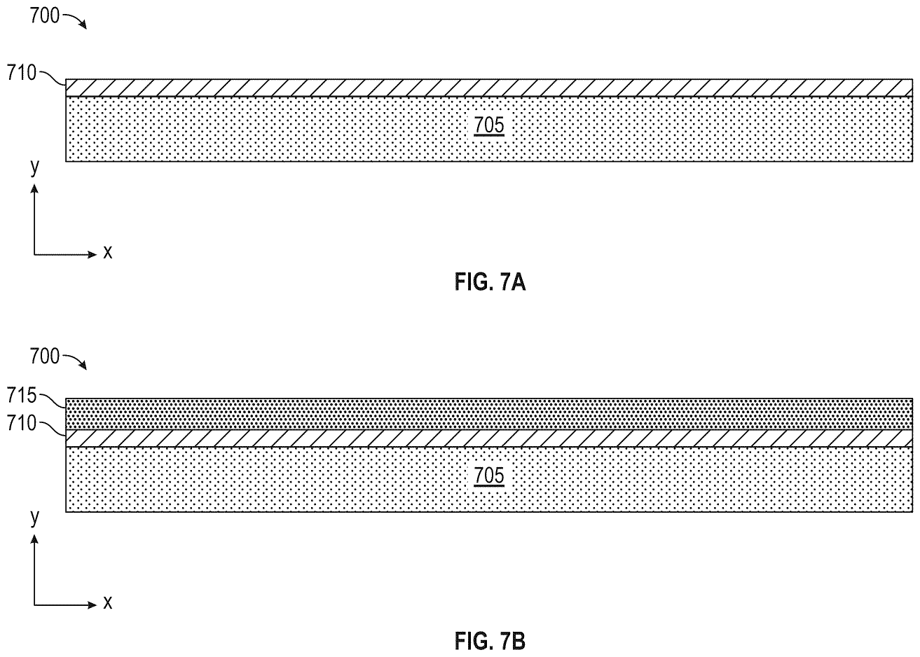

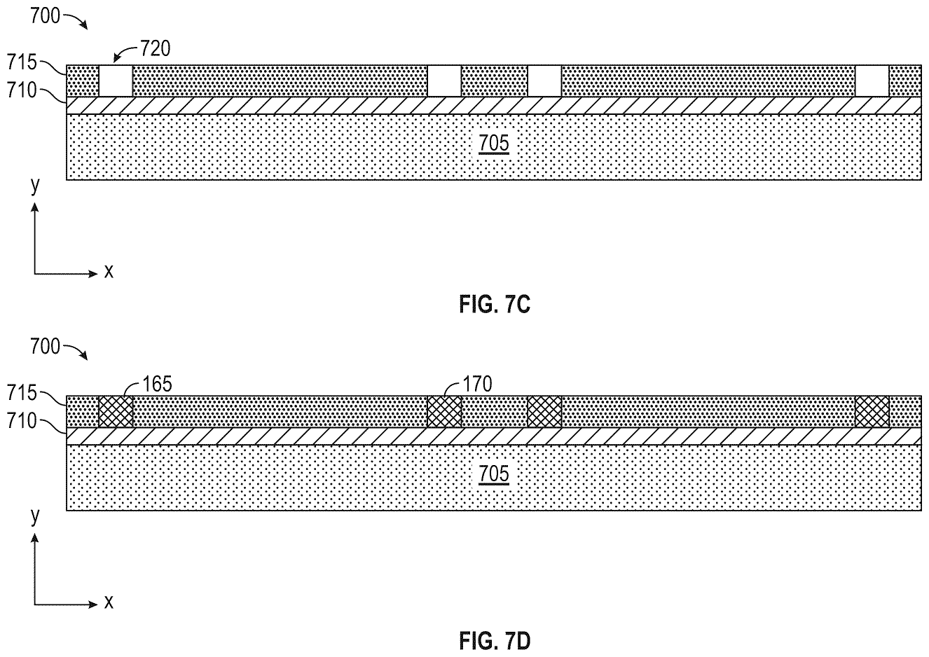

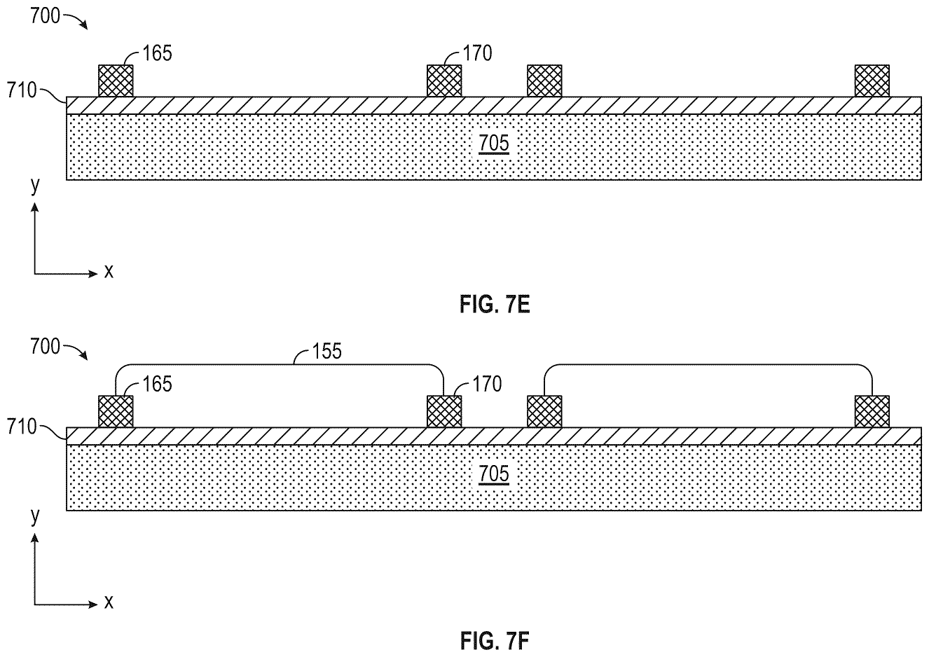

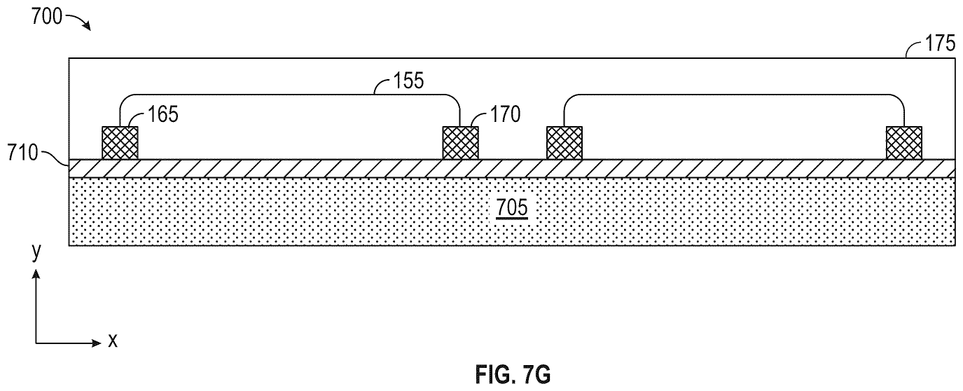

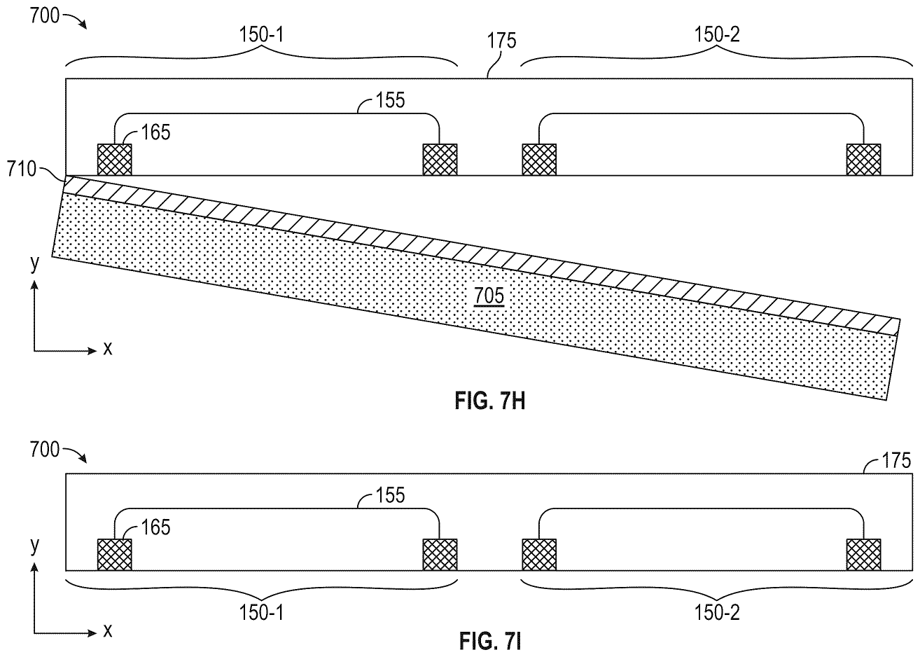

FIG. 5 is a flowchart of an example method 500 of forming an interposer (e.g., the interposer 150) described herein. In some implementations, and as described in greater detail in connection with FIGS. 7A-7I, one or more process blocks of FIG. 5 may be performed by various semiconductor manufacturing equipment.

As shown in FIG. 5, the method 500 may include forming, over a temporary carrier, a pattern of conductive input structures (e.g., a pattern of the input structures 165) and a pattern of conductive output structures (e.g., a pattern of the output structures 170) (block 510). As further shown in FIG. 5, the method 500 may include forming a pattern of conductive wires (e.g., the pattern of wire bonds 155) that connect the pattern of conductive input structures and the pattern of conductive output structures, wherein each conductive wire of the pattern of conductive wires electrically couples a unique pair of conductive input and output structures (block 520). As further shown in FIG. 5, the method 500 may include forming a casing (e.g., the casing 175) that surrounds the pattern of conductive wires (block 530). As further shown in FIG. 5, the method 500 may include removing the temporary carrier to form an interposer (e.g., the interposer 150) that provides a rerouting of electrical signals from the conductive input structures to the conductive output structures using the pattern of conductive wires (block 540).

The method 500 may include additional aspects, such as any single aspect or any combination of aspects described below and/or in connection with one or more other methods described elsewhere herein.

In a first aspect, forming the pattern of conductive input structures and the pattern of conductive output structures includes forming the pattern of conductive input structures and the pattern of conductive output structures on a release film that is joined with a glass carrier.

In a second aspect, alone or in combination with the first aspect, removing the temporary carrier includes debonding the casing from the release film.

In a third aspect, alone or in combination with one or more of the first and second aspects, forming the pattern of conductive input structures and the pattern of conductive output structures on the release film includes forming a masking layer on the release film, forming openings in the masking layer, and forming the pattern of conductive input structures and the pattern of conductive output structures in the openings using an electroplating process.

In a fourth aspect, alone or in combination with one or more of the first through third aspects, forming the masking layer on the release film includes depositing a layer of photoresist on the release film, and forming the openings in the masking layer includes exposing and developing the openings using a lithography process.

In a fifth aspect, alone or in combination with one or more of the first through fourth aspects, forming the pattern of conductive wires includes forming the pattern of conductive wires using a thermosonic wire bonding operation, forming the pattern of conductive wires using a thermocompression wire bonding operation, forming the pattern of conductive wires using an ultrasonic wire bonding operation, forming the pattern of conductive wires using a wedge bonding operation, or forming the pattern of conductive wires using a ribbon bonding operation.

In a sixth aspect, alone or in combination with one or more of the first through fifth aspects, forming the casing includes forming the casing using a transfer molding operation, a compression molding operation, an injection molding operation, or a liquid encapsulation molding operation.

In a seventh aspect, alone or in combination with one or more of the first through sixth aspects, the interposer is a first interposer and the method 500 further includes separating the first interposer from a second, adjacent interposer using a singulation operation.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the interposer 150, an integrated assembly that includes the interposer 150, any part described herein of the interposer 150, and/or any part described herein of an integrated assembly that includes the interposer 150. For example, the method 500 may include forming one or more of the apparatus 100 or the device 200.

FIG. 6 is a flowchart of an example method 600 of forming an integrated assembly or device (e.g., the apparatus 100 or the device 200) having an interposer (e.g., the interposer 150) described herein. In some implementations, one or more process blocks of FIG. 6 may be performed by various semiconductor manufacturing equipment at an original equipment manufacturer (OEM) or an outsourced assembly and test (OSAT) facility.

As shown in FIG. 6, the method 600 may include placing a first integrated circuit (e.g., the integrated circuit 105-1) on a substrate (e.g., the substrate 110) (block 610). As further shown in FIG. 6, the method 600 may include placing a second integrated circuit (e.g., the integrated circuit 105-2) on the substrate (block 620). As further shown in FIG. 6, the method 600 may include electrically coupling the first integrated circuit and the second integrated circuit using an interposer (e.g., the interposer 150) that includes a pattern of wire bonds (e.g., the pattern of wire bonds 155) used to redistribute electrical signals from inputs (e.g., the input structures 165) of the interposer to outputs (e.g., the output structures 170) of the interposer and a casing (e.g., the casing 175) that surrounds the pattern of wire bonds (block 630).

The method 600 may include additional aspects, such as any single aspect or any combination of aspects described below and/or in connection with one or more other methods described elsewhere herein.

Although FIG. 6 shows example blocks of the method 600, in some implementations, the method 600 may include additional blocks, fewer blocks, different blocks, or differently arranged blocks than those depicted in FIG. 6. In some implementations, the method 600 may include forming the interposer 150, an integrated assembly that includes the interposer 150, any part described herein of the interposer 150, and/or any part described herein of an integrated assembly that includes the interposer 150. For example, the method 600 may include forming one or more of the apparatus 100 or the device 200, where the apparatus 100 or the device 200 is a semiconductor package, a multi-die semiconductor package, a memory module, a solid state drive, a server board, a graphics card, a network interface card, a backplane interface board, or a power supply board, among other examples.

FIGS. 7A-7I are diagrammatic views showing formation of an interposer (e.g., the interposer 150) at stages of an example process 700 of forming the interposer. In some implementations, the example process described below in connection with FIGS. 7A-7I may correspond to the method 500 and/or one or more blocks of the method 500. However, the process described below is an example, and other example processes may be used to form the interposer 150.

As shown in FIG. 7A, the process 700 may include receiving a temporary carrier 705 and forming a release film 710 on the temporary carrier 705. The temporary carrier 705 may be a glass carrier, a ceramic carrier, or another suitable carrier, among other examples. The release film 710 may be a polyimide release film, an ultraviolet curable release film, a fluoropolymer release film, a thermoplastic release film, or another suitable release film, among other examples. In some implementations, a lamination tool attaches the release film 710 to a top surface of temporary carrier 705 using a lamination operation, among other examples.

As shown in FIG. 7B, the process 700 may include forming masking layer 715 over and/or on the release film 710. The masking layer 715 may include a photoresist material, a hard mask material (e.g., an oxide material or a nitride material), or another suitable material, among other examples. In some implementations, and as an example, a photoresist dispense tool forms a layer of photoresist material on the release film 710 using a coating operation, among other examples. Alternatively, and in some implementations, a deposition tool forms the masking layer 715 using a CVD operation, a PVD operation, or another suitable deposition operation that deposits a hard mask material on the release film 710, among other examples.

As shown in FIG. 7C, the process 700 may include forming openings 720 (e.g., cavities) through the masking layer 715. As an example, and in a case in which the masking layer 715 includes a photoresist material, an exposure tool may expose a pattern corresponding to the openings 720 in the photoresist material and a develop tool may remove portions of the photoresist material to form the openings 720. Alternatively, and in a case in which the masking layer 715 includes a hard mask material, a set of deposition and lithography tools may perform a series of operations to form a masking pattern corresponding to the openings 720 over and/or on the masking layer 715, and an etch tool may remove portions of the hard mask material to form the openings 720.

As shown in FIG. 7D, the process 700 may include forming the input structures 165 (e.g., a pattern of conductive input structures) and/or the output structures 170 (e.g., a pattern of conductive output structures) in the openings 720. In some implementations, and as an example, a deposition tool forms the input structures 165 and/or the output structures 170 using an electroplating operation. In some implementations, and as another example, a deposition tool forms the input structures 165 and/or the output structures 170 using a PVD operation, a CVD operation, or another suitable deposition operation, among other examples.

As shown in FIG. 7E, the process 700 may include removing the masking layer 715 to reveal the input structures 165 and the output structures 170. In a case in which the masking layer 715 includes a photoresist material, and as an example, an asher tool may remove the masking layer 715 using an ashing operation. Alternatively, and in a case in which the masking layer 715 includes a hard mask material, an etch tool may remove the masking layer 715 using a wet etch operation, a dry etch operation, or another suitable etch operation, among other examples.

As shown in FIG. 7F, the process 700 may include forming the pattern of wire bonds 155 (e.g., a pattern of conductive wires) that connect the input structures 165 and the output structures 170. In some implementations, each wire bond (e.g., each conductive wire) of the pattern of wire bonds 155 electrically couples a unique pair of the input structures 165 and the output structures 170. In some implementations, a wire bond tool forms the pattern of wire bonds 155 using a thermosonic wire bonding operation, a thermocompression wire bonding operation, an ultrasonic wire bonding operation, a wedge bonding operation, a ribbon bonding operation, or another suitable wire bonding operation, among other examples.

As shown in FIG. 7G, the process 700 may include forming the casing 175 that surrounds the pattern of wire bonds 155. In some implementations, a molding tool forms the casing 175 using a transfer molding operation, a compression molding operation, an injection molding operation, a liquid encapsulation molding operation, or another suitable molding operation, among other examples.

As shown in FIG. 7H, the process 700 may include removing (e.g., debonding) the temporary carrier 705 from the casing 175. In some implementations, a debonding tool removes the temporary carrier 705 using a UV exposure operation that radiates UV light onto the release film 710, a heating operation that applies heat to the release film 710, or another suitable debonding operation that separates the release film 710 from the casing 175, among other examples. As shown in FIG. 7H, and after removing the temporary carrier 705, one or more interposers 150 (e.g., the interposer 155-1 and the interposer 155-2) are joined together in a matrix form.

As shown in FIG. 7I, the process 700 may include separating the interposer 150-1 (e.g., a first interposer) from the interposer 150-2 (e.g., a second, adjacent interposer). In some implementations, a singulation tool separates the interposers 150-1 and 150-2 using a singulation operation that includes dicing, sawing, or ablating the casing 175 between the interposer 150-1 and the interposer 150-2, among other examples.

As indicated above, the process steps described in connection with FIGS. 7A-7I are provided as examples. Other examples may differ from what is described with respect to FIGS. 7A-7I. The structure shown in FIG. 7I may be equivalent to the interposer 150 described elsewhere herein.

In some implementations, a semiconductor device assembly includes an integrated circuit die; a substrate; and an interposer that electrically couples the integrated circuit die and the substrate, the interposer comprising: a pattern of wire bonds used to redistribute electrical signals from inputs of the interposer to outputs of the interposer; and an epoxy mold compound that surrounds the pattern of wire bonds.

In some implementations, an apparatus includes a first integrated circuit; a second integrated circuit; an interposer that is part of an electrical circuit that electrically couples the first integrated circuit and the second integrated circuit, the interposer comprising: a casing; and at least one malleable, conductive wire that is embedded in the casing and that is contoured to reroute a signal through the casing.

In some implementations, an apparatus includes an interposer that is void of active integrated circuitry, comprising: a plurality of wire bonds; a casing that surrounds the plurality of wire bonds; first electrical contacts exposed at a surface of the casing that connect to first ends of the plurality of wire bonds; and second electrical contacts exposed at the surface of the casing that connect to second ends of the plurality of wire bonds.

In some implementations, a method includes forming, over a temporary carrier, a pattern of conductive input structures and a pattern of conductive output structures; forming a pattern of conductive wires that connect the pattern of conductive input structures and the pattern of conductive output structures, wherein each conductive wire of the pattern of conductive wires electrically couples a unique pair of conductive input and output structures; forming a casing that surrounds the pattern of conductive wires; and removing the temporary carrier to form an interposer that provides a rerouting of electrical signals from the conductive input structures to the conductive output structures using the pattern of conductive wires.

In some implementations, a method includes placing a first integrated circuit on a substrate; placing a second integrated circuit on the substrate; electrically coupling the first integrated circuit and the second integrated circuit using an interposer that includes a pattern of wire bonds used to redistribute electrical signals from inputs of the interposer to outputs of the interposer and a casing that surrounds the pattern of wire bonds.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
an integrated circuit die;
a substrate; and
an interposer that electrically couples the integrated circuit die and the substrate, the interposer comprising:
a pattern of wire bonds used to redistribute electrical signals from inputs of the interposer to outputs of the interposer; and
an epoxy mold compound that surrounds the pattern of wire bonds.

2. The semiconductor device assembly of claim 1, wherein the pattern of wire bonds includes at least one wire bond that follows a non-linear path between an input and an output of the interposer.

3. The semiconductor device assembly of claim 1, wherein the inputs and the outputs are exposed at a surface of the interposer that faces away from the substrate, and
wherein the inputs and the outputs are between the pattern of wire bonds and the surface.

4. The semiconductor device assembly of claim 1, further comprising:
a first wire bond that electrically couples the integrated circuit die to an input of the interposer, and
a second wire bond that electrically couples an output of the interposer to the substrate,
wherein a second path of the second wire bond is approximately orthogonal to a first path of the first wire bond.

5. The semiconductor device assembly of claim 1, wherein the interposer is on the substrate.

6. The semiconductor device assembly of claim 1, wherein that integrated circuit die is a first integrated circuit die, and
wherein the interposer is on a second integrated circuit die that is on the substrate.

7. An apparatus, comprising:
a first integrated circuit;
a second integrated circuit;
an interposer that is part of an electrical circuit that electrically couples the first integrated circuit and the second integrated circuit, the interposer comprising:
a casing; and
at least one malleable, conductive wire that is embedded in the casing and that is contoured to reroute a signal through the casing.

8. The apparatus of claim 7, wherein the first integrated circuit and the second integrated circuit are over a substrate, and
wherein the electrical circuit includes a trace within the substrate.

9. The apparatus of claim 7, wherein the apparatus corresponds to:
a multi-die semiconductor package,
a memory module,
a solid state drive,
a server board,
a graphics card,
a network interface card,
a backplane interface board, or
a power supply board.

10. The apparatus of claim 7, wherein the electrical circuit comprises:
a wire bond that electrically couples a pad structure of the interposer with a pad structure of a printed circuit board,
wherein the pad structure of the printed circuit board is included in an L-shaped pattern of pad structures.

11. The apparatus of claim 7, wherein the first integrated circuit or the second integrated circuit comprises NAND integrated circuitry.

12. The apparatus of claim 7, wherein the first integrated circuit or the second integrated circuit comprises application specific integrated circuitry.

13. An interposer, comprising:
a plurality of wire bonds;
a casing that surrounds the plurality of wire bonds;
first wire bond pads exposed at a surface of the casing that connect to first ends of the plurality of wire bonds; and
second wire bond pads exposed at the surface of the casing that connect to second ends of the plurality of wire bonds.

14. The interposer of claim 13, wherein the first wire bond pads are along a first edge of the casing, and
wherein the second wire bond pads comprise:
a first subset along a second edge of the casing that is approximately orthogonal to the first edge, and
a second subset along a third edge of the casing that is approximately orthogonal to the first edge and opposite the second edge.

15. The interposer of claim 14, wherein the interposer further comprises at least one passive integrated circuit component that is electrically coupled with at least one of the plurality of wire bonds.

16. The interposer of claim 15, wherein the passive integrated circuit component is:
a resistor component,
a capacitor component, or
an inductor component.

17. The interposer of claim 15, wherein the wire bond pads and the second wire bond pads are embedded in the casing.

18. A method, comprising:
forming, over a temporary carrier, a pattern of conductive input structures and a pattern of conductive output structures;
forming a pattern of conductive wires that connect the pattern of conductive input structures and the pattern of conductive output structures,
wherein each conductive wire of the pattern of conductive wires electrically couples a unique pair of conductive input and output structures;
forming a casing that surrounds the pattern of conductive wires; and
removing the temporary carrier to form an interposer that provides a rerouting of electrical signals from the conductive input structures to the conductive output structures using the pattern of conductive wires.

19. The method of claim 18, wherein forming the pattern of conductive input structures and the pattern of conductive output structures includes:
forming the pattern of conductive input structures and the pattern of conductive output structures on a release film that is joined with a glass carrier.

20. The method of claim 19, wherein removing the temporary carrier includes:
debonding the casing from the release film.

21. The method of claim 19, wherein forming the pattern of conductive input structures and the pattern of conductive output structures on the release film includes:
forming a masking layer on the release film,
forming openings in the masking layer, and
forming the pattern of conductive input structures and the pattern of conductive output structures in the openings using an electroplating process.

22. The method of claim 21, wherein forming the masking layer on the release film includes depositing a layer of photoresist on the release film, and
wherein forming the openings in the masking layer includes:
exposing and developing the openings using a lithography process.

23. The method of claim 18, wherein forming the pattern of conductive wires includes:
forming the pattern of conductive wires using a thermosonic wire bonding operation,
forming the pattern of conductive wires using a thermocompression wire bonding operation,
forming the pattern of conductive wires using an ultrasonic wire bonding operation,
forming the pattern of conductive wires using a wedge bonding operation, or
forming the pattern of conductive wires using a ribbon bonding operation.

24. The method of claim 18, wherein forming the casing includes:
forming the casing using a transfer molding operation,
forming the casing using a compression molding operation,
forming the casing using an injection molding operation, or
forming the casing using a liquid encapsulation molding operation.

25. The method of claim 18, wherein the interposer is a first interposer and further comprising:
separating the first interposer from a second, adjacent interposer using a singulation operation.
